(19) United States
(12) Patent Application Publication
(10) Pub. No.: US 2016/0380126 A1
(43) Pub. Date: Dec. 29, 2016

(54) MULTI-LAYER BARRIER FOR METALLIZATION

(71) Applicants: David Aaron Randolph Barkhouse, Menlo Park, CA (US); Todd Richards Johnson, San Jose, CA (US); Paul Loscutoff, Castro Valley, CA (US); Robert Woehl, San Jose, CA (US)

(72) Inventors: David Aaron Randolph Barkhouse, Menlo Park, CA (US); Todd Richards Johnson, San Jose, CA (US); Paul Loscutoff, Castro Valley, CA (US); Robert Woehl, San Jose, CA (US)

(21) Appl. No.: 14/751,096

(22) Filed: Jun. 25, 2015

(51) Int. Cl. H01L 31/0224; H01L 31/18

(52) U.S. Cl. CPC H01L 31/022425; H01L 31/18

(57) ABSTRACT

A solar cell can include a substrate, a semiconductor region disposed in or above the substrate, and a conductive stack that includes a first conductive region, a multi-layer barrier region, and a second conductive region.

### BACKGROUND

Photovoltaic cells, commonly known as solar cells, are devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency and/or cost in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

### BRIEF DESCRIPTION OF THE DRAWINGS

FIG. 1 illustrates a cross-sectional view of a portion of a solar cell having contact structures formed on emitter regions formed above a substrate, in accordance with an embodiment of the present disclosure.

FIG. 2 illustrates a cross-sectional view of a portion of a solar cell having contact structures formed on emitter regions formed in a substrate, in accordance with an embodiment of the present disclosure.

FIG. 3 is a flowchart illustrating operations in a method of fabricating a solar cell, in accordance with an embodiment of the present disclosure.

FIGS. 4-9 illustrate cross-sectional views of various processing operations in another method of fabricating solar cells having contact structures, in accordance with an embodiment of the present disclosure.

FIGS. 10, 11A, and 11B illustrate graphs of efficiency and short circuit current for example metallization structures.

FIG. 12 illustrates SEM cross-section images for example metallization structures.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” barrier region does not necessarily imply that this barrier region is the first barrier region in a sequence; instead the term “first” is used to differentiate this barrier region from another barrier region (e.g., a “second” barrier region).

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Approaches for the metallization of solar cells and the resulting solar cells are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as lithography and patterning techniques, are not described in detail in order to not unnecessarily obscure embodiments of the present disclosure. Furthermore, it is to be understood that the various embodiments shown in the figures are illustrative representations and are not necessarily drawn to scale.

The specification first describes example solar cells having a multi-layer barrier region configured to inhibit diffusion of metal to other metal and/or metal to silicon. An example method for fabricating a solar cell having a multi-layer barrier region is then described. Numerous examples are provided throughout the specification. Although many of the described examples are back-contact solar cells, the multi-layer barrier region can apply in other contexts, for example, for front-contact metallization for solar cells or for metal structures for semiconductor devices.

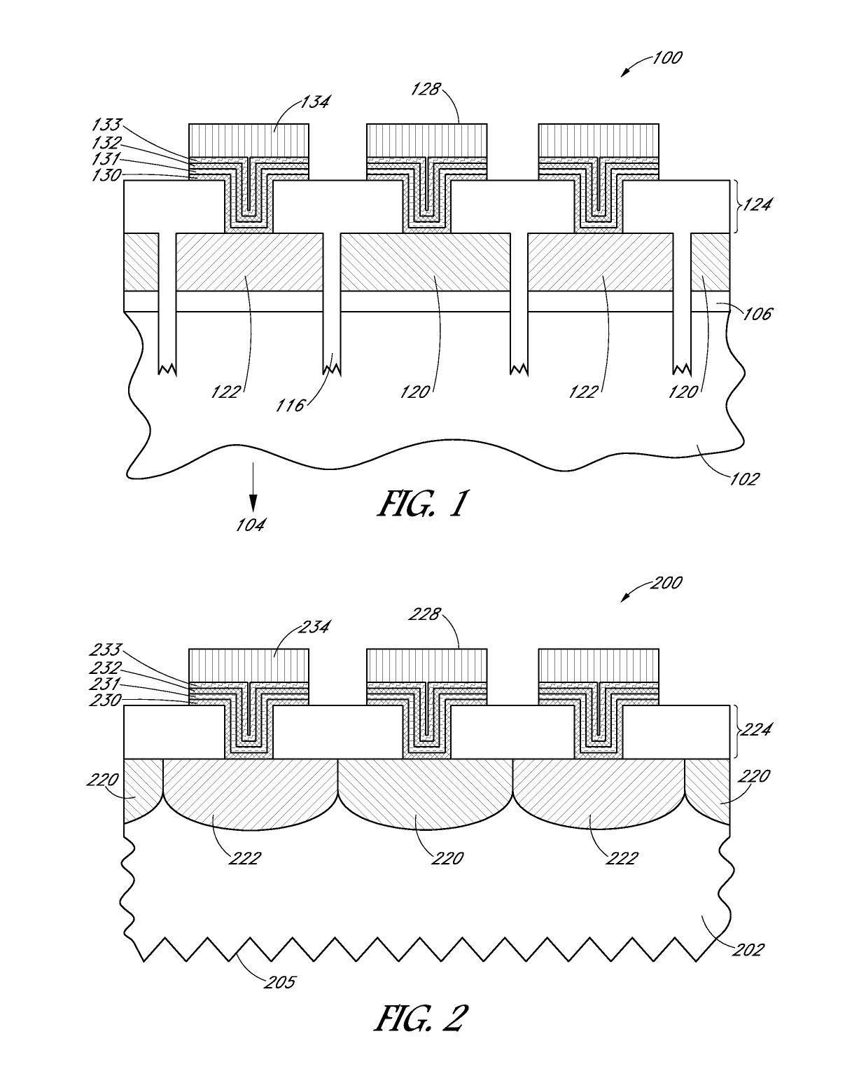

Referring to FIG. 1, a portion of an example solar cell that includes a multi-layer barrier region is illustrated. As shown, solar cell 100 can include patterned dielectric layer 124 disposed above a plurality of n-type doped polysilicon regions 120, a plurality of p-type doped polysilicon regions 122, and on portions of a substrate 102 exposed by trenches 116. Contact structures 128 are disposed in a plurality of contact openings disposed in the dielectric layer 124 and are coupled to the plurality of n-type doped polysilicon regions 120 and to the plurality of p-type doped polysilicon regions 122.

Trenches 116 can be formed between n-type doped polysilicon regions 120 and p-type doped polysilicon regions 122. Portions of the trenches 116 can be texturized to have textured features. A dielectric layer 124 can be formed above the plurality of n-type doped polysilicon regions 120, the plurality of p-type doped polysilicon regions 122, and the portions of substrate 102 exposed by trenches 116. In one embodiment, a lower surface of the dielectric layer 124 is formed conformal with the plurality of n-type doped polysilicon regions 120, the plurality of p-type doped polysilicon regions 122, and the exposed portions of substrate 102, while an upper surface of dielectric layer 124 is substantially flat. In a specific embodiment, the dielectric layer 124 is an anti-reflective coating (ARC) layer.

In embodiments, a plurality of contact openings can be formed in the dielectric layer 124. The plurality of contact openings can provide exposure to the plurality of n-type doped polysilicon regions 120 and to the plurality of p-type doped polysilicon regions 122. In one embodiment, the plurality of contact openings is formed by laser ablation.

Furthermore, the plurality of n-type doped polysilicon regions 120 and the plurality of p-type doped polysilicon regions 122 can, in one embodiment, provide emitter regions for the solar cell 100. Thus, in an embodiment, the contact structures 128 are disposed on the emitter regions. In an embodiment, the contact structures 128 are back contacts for a back-contact solar cell and are situated on a surface of the solar cell opposing a light receiving surface (direction provided as 104 in FIG. 1) of the solar cell 100. Furthermore, in one embodiment, the emitter regions can be formed on a thin or tunnel dielectric layer 106. The thin dielectric layer 106 can be composed of silicon dioxide and can have a thickness approximately in the range of 5-50 Angstroms. In one embodiment, the thin dielectric layer 106 performs as a tunneling oxide layer. In one such embodiment, the term “tunneling oxide layer” refers to a very thin (e.g., less than approximately 10 nm) dielectric layer, through which electrical conduction can be achieved. The conduction may be due to quantum tunneling and/or the presence of small regions of direct physical connection through thin spots in the dielectric layer.

In an embodiment, substrate 102 is a bulk monocrystalline silicon substrate, such as an n-type doped monocrystalline silicon substrate. However, in an alternative embodiment, substrate 102 includes a polycrystalline silicon layer disposed on a global solar cell substrate. Moreover, in some embodiments, substrate 102 can be a multicrystalline silicon substrate.

In some embodiments, each of the contact structures 128 can include a seed stack disposed on the emitter regions of solar cell 100. The seed stack can include first conductive region 130, multi-layer barrier region 131 and 132 disposed on the first conductive region, and in some embodiments, second conductive region 133 disposed on the multi-layer barrier region. Although the multi-layer barrier region is illustrated as two layers, first and second barrier regions 131 and 132, in other examples, the multi-layer barrier region can include more than two layers.

Also as illustrated, contact structure 128 can include an additional conductive region 134 disposed on second conductive region 133. As one example, conductive region 134 can include plated metal, such as plated nickel, plated copper, and/or plated tin, among other examples. In some embodiments, as described herein, the seed stack may not itself include second conductive region 133 but instead, the additional conductive region (e.g., plated metal) may be disposed directly on the multi-layer barrier region, for example, as plated metal disposed directly on the multi-layer barrier region. In such an example, the additional metal disposed on the multi-layer barrier region may be referred to as a second conductive region.

In one embodiment, first conductive region 130 can be a metal-containing region. For example, first conductive region 130 can include aluminum (Al) and/or an aluminum/silicon (Al/Si) alloy. In one embodiment, the first conductive region is approximately 50-100 nanometers (nm) thick.

In various embodiments, the multi-layer barrier region can include first barrier region 131, closest to the substrate that is selective to inhibit diffusion from or to first conductive region 130 and/or from or to second barrier region 132. Similarly, second barrier region 132, farther from the substrate than first barrier region 131, can be selective to inhibit diffusion from or to second conductive region 133 and/or from or to first barrier region 132.

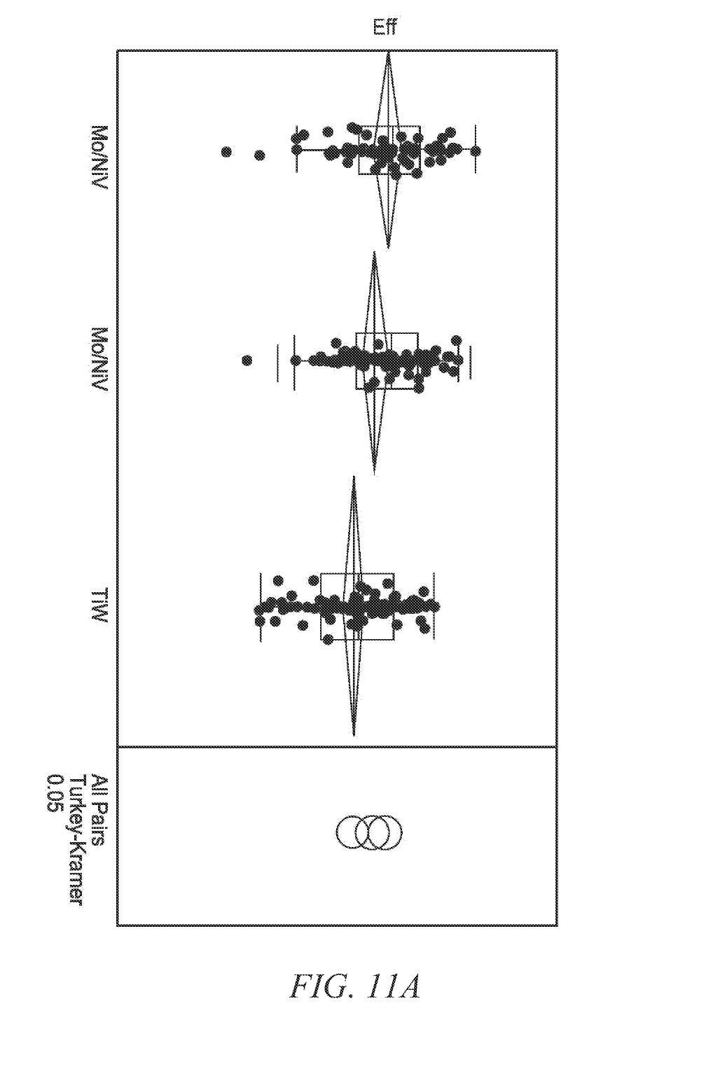

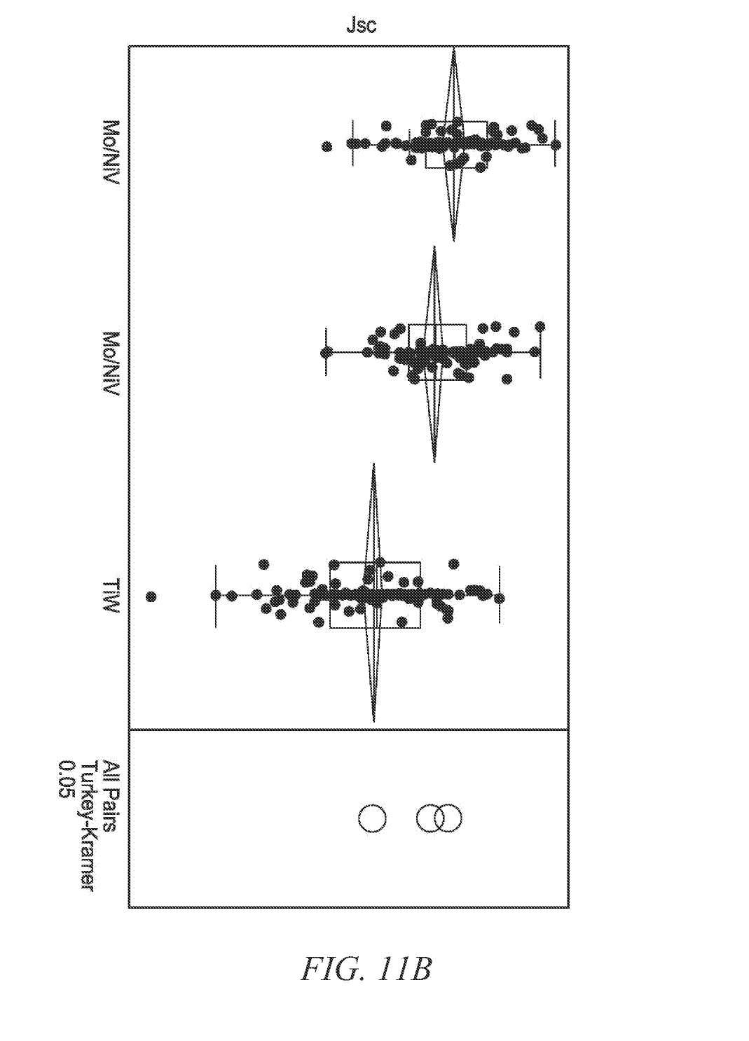

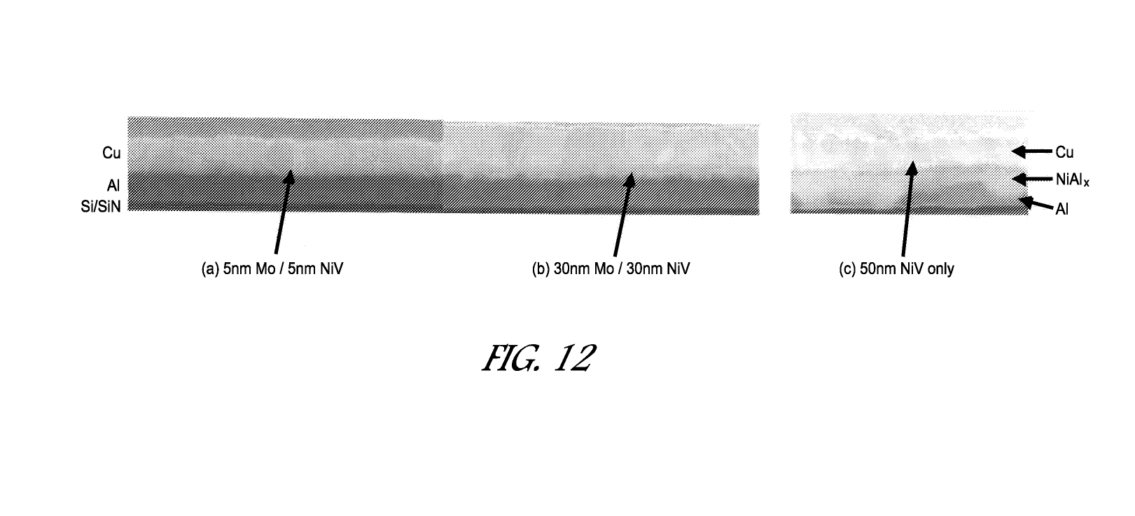

In some embodiments, a barrier layer containing TiW may make up two-thirds of the material cost of the seed stack and may also need a complex multi-step and expensive etching process to pattern the TiW and other metals of the seed stack. Additionally, in some instances, some barrier layers can flake more than others such that preventive maintenance for manufacturing equipment must be performed more frequently. Moreover, single layer barrier layers that are lower cost and easier to etch such as Mo or Ni may suffer from performance issues, as shown and described at FIG. 11. One thing that the inventors realized is that by using a multi-layer barrier region, a lower cost, yet as efficient device can be fabricated.

In one embodiment, one or more of the barrier regions can be diffusion-barrier conductive layers, and can include a refractory metal, such as tungsten (W) and/or molybdenum (Mo), and in some embodiments, can include a near-noble or transition metal (e.g., titanium (Ti)). In some embodiments, nickel or a nickel alloy can be used as a barrier region. In one particular example, first barrier region can include Mo (e.g., Mo, Mo—Ti alloy) and the second barrier region can include Ni (e.g., Ni-vanadium alloy, Ni-chromium alloy) and/or Ti.

In various embodiments, the collective multi-layer barrier region can be formed such that it has one or more of the following properties: low solubility of the first and second regions (e.g., Al and Cu) at a range of temperatures (e.g., up to an annealing temperature of approximately 400 degrees Celsius) and not be reactive with either of the first or second regions, have a grain structure that is not conducive to the transport of the metals of the conductive regions along grain boundaries, etch in a low-cost etch chemistry, and/or have good sputtering properties (e.g., electrically and thermally conductive, inhibits flaking).

In some embodiments, the thickness of the multi-layer barrier region can be approximately 60 nanometers (nm) or less but in some examples can be thicker than 60 nm, for example, 100 nm. In some examples, the thickness can be approximately 10 nm or less and still adequately inhibit diffusion. For example, in one embodiment, a first diffusion region of approximately 5 nm of Mo and a second diffusion region of approximately 5 nm of nickel-vanadium (NiV) can be used and the resulting solar cell structure can achieve state of the art efficiency and short circuit current, among other metrics of performance. Utilizing such a thin and lower cost barrier region can reduce material cost significantly and also speed throughput of the deposition and/or patterning processes by reducing the amount of time needed to deposit and/or etch the stack. Although the example above assumed an approximately equal thickness of the first and second barrier regions, in some embodiments, the thickness of the barrier regions can be different from one another. For example, in one embodiment, the thickness of a Mo barrier region can be approximately 5 nm and the thickness of the NiV barrier region can be approximately 10 nm. Other examples also exist.

Although the illustrated examples show a two-layer barrier stack, in other embodiments, the multi-layer barrier stack can include more than two layers. Each region/layer can have a distinct composition (e.g., Mo first barrier region, Ti second barrier region, NiV third barrier region) or one layer can repeat (e.g., Mo first barrier region, NiV second barrier region, Mo third barrier region).

In various embodiments, the described barrier regions in the multi-layer barrier stack can have high crystallization temperatures, which can allow them to be deposited in an amorphous or small-grained state, which can reduce the rate of grain boundary diffusion through the barriers.

In one embodiment, as was the case with first conductive region 130, second conductive region 133 can also be a metal-containing region. Second conductive region 133 can be copper, among other examples. In one embodiment, the second conductive region is approximately 50-200 nanometers (nm) thick.

In embodiments, the layers/regions of the seed stack can be formed on the semiconductor region by sputtering or other deposition technique. Various ones of the regions of the seed stack may include solvents, frit material, and/or binders to make the paste viscous enough and adhesive enough for deposition or other application to the semiconductor region.

In an embodiment, contact structure 128 can further include an additional conductive region, for example, approximately 35 microns of plated Cu.

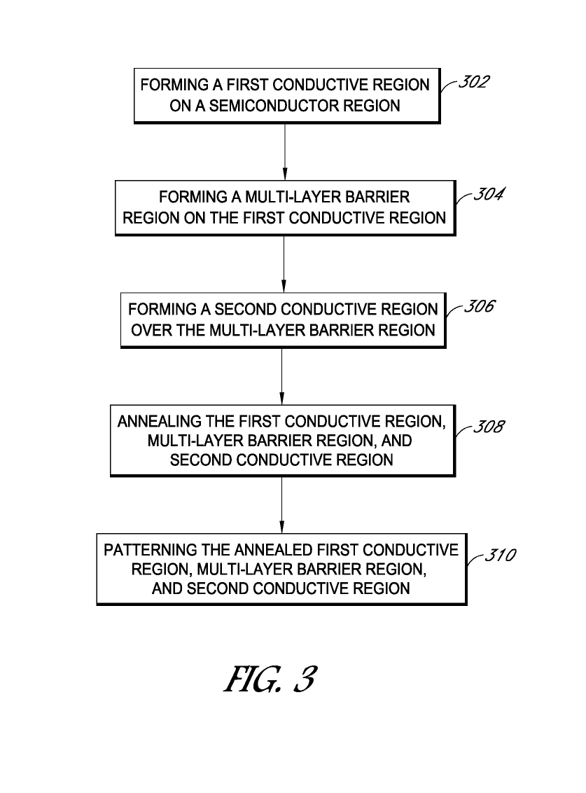

In a second exemplary cell, a multi-layer barrier stack is used for a solar cell having emitter regions formed in a substrate of the solar cell. For example, FIG. 2 illustrates a cross-sectional view of a portion of a solar cell having contact structures formed on emitter regions formed in a substrate, in accordance with an embodiment of the present disclosure.

Referring to FIG. 2, a portion of a solar cell 200 can include a patterned dielectric layer 224 disposed above a plurality of n-type doped diffusion regions 220, a plurality of p-type doped diffusion regions 222, and on portions of a substrate 202, such as a bulk crystalline silicon substrate (e.g., n-type monocrystalline substrate). Contact structures 228 can be disposed in a plurality of contact openings disposed in the dielectric layer 224 and can be coupled to the plurality of n-type doped diffusion regions 220 and to the plurality of p-type doped diffusion regions 222. In an embodiment, the diffusion regions 220 and 222 are formed by doping regions of a silicon substrate with n-type dopants and p-type dopants, respectively.

Furthermore, the plurality of n-type doped diffusion regions 220 and the plurality of p-type doped diffusion regions 222 can, in one embodiment, provide emitter regions for the solar cell 200. Thus, in an embodiment, the contact structures 228 are disposed on the emitter regions. In an embodiment, the contact structures 228 are back contacts for a back-contact solar cell and are situated on a surface of the solar cell opposing a light receiving surface, such as opposing a texturized light receiving surface 205, as depicted in FIG. 2. In an embodiment, referring again to FIG. 2, each of the contact structures 228 can include a seed stack that includes first conductive region 230, a multi-layer barrier region (e.g., barrier region 231 and barrier region 232), second conductive region 233, and a third conductive region 234. The description of contact structure 128 and the multi-layer barrier region of FIG. 1 applies equally to contact structure 228 and the multi-layer barrier region of FIG. 2 and is not repeated for brevity and ease of understanding.

Although certain materials are described specifically above with reference to FIGS. 1 and 2, some materials may be readily substituted with others with other such embodiments remaining within the spirit and scope of embodiments of the present disclosure. For example, in an embodiment, a different material substrate, such as a group III-V material substrate, can be used instead of a silicon substrate. In another embodiment, silver (Ag), (e.g., Ag particles) or the like can be used in a conductive layer in addition to, or instead of Al, (or Al alloy) or Cu (or Cu alloy) particles.

Furthermore, the formed contacts need not be formed directly on a bulk substrate, as was described in FIG. 2. For example, in one embodiment, contact structures such as those described above are formed on semiconducting regions formed above (e.g., on a back side of) as bulk substrate, as was described for FIG. 1.

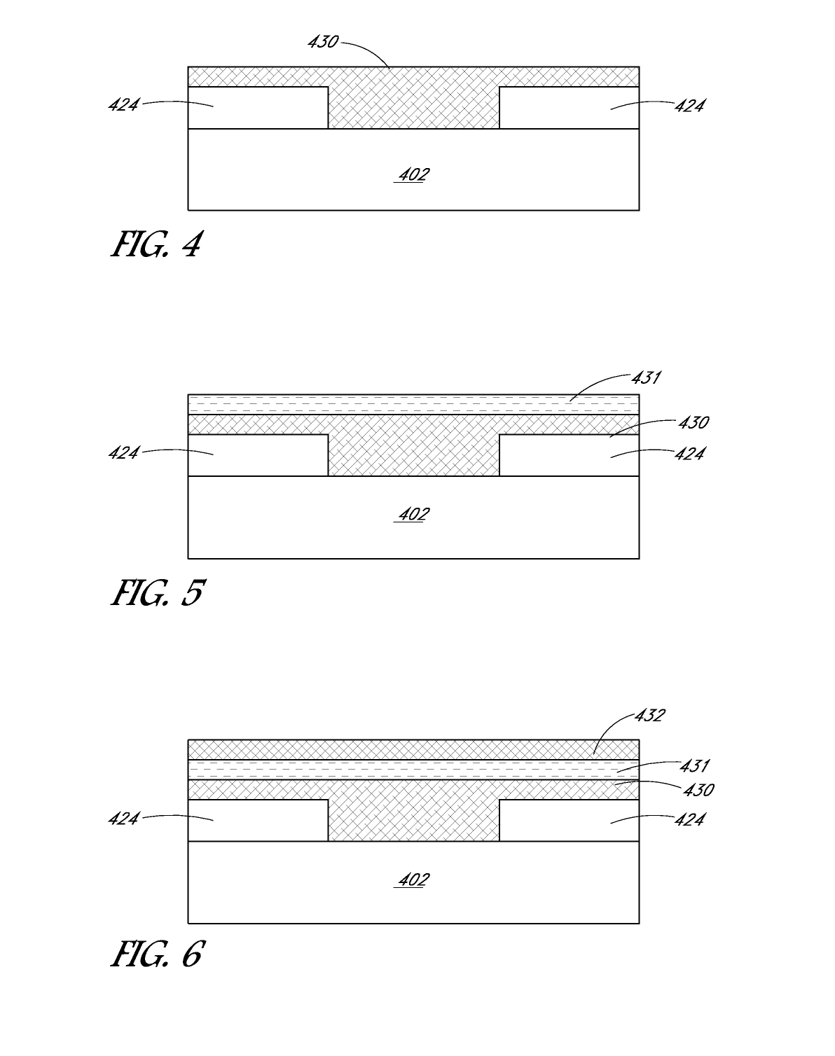

Turning now to FIG. 3, a flow chart illustrating a method for fabricating a solar cell is shown, according to some embodiments. In various embodiments, the method of FIG. 3 may include additional (or fewer) blocks than illustrated. For example, in one embodiment, additional metal may be plated on the second conductive region. Moreover, in various embodiments, the blocks of the flow chart illustrated in FIG. 3 may be performed in a different order than shown. FIGS. 4-9 illustrate cross-sectional views of various processing operations in the method of FIG. 3.

As shown at 302, a first conductive region can be formed on a semiconductor region disposed in or above a substrate. An example of forming first conductive region 430 formed on the semiconductor region (not shown) disposed in or above substrate 402 is shown in FIG. 4. Also illustrated is dielectric 424. As described herein, the first conductive region can be a metal-containing region, such as aluminum or an aluminum alloy (e.g., Al—Si). The first conductive region can be formed by deposition, such as by sputtering, although other examples also exist. In various embodiments, the first conductive region can be formed at a thickness of approximately 50-100 nm.

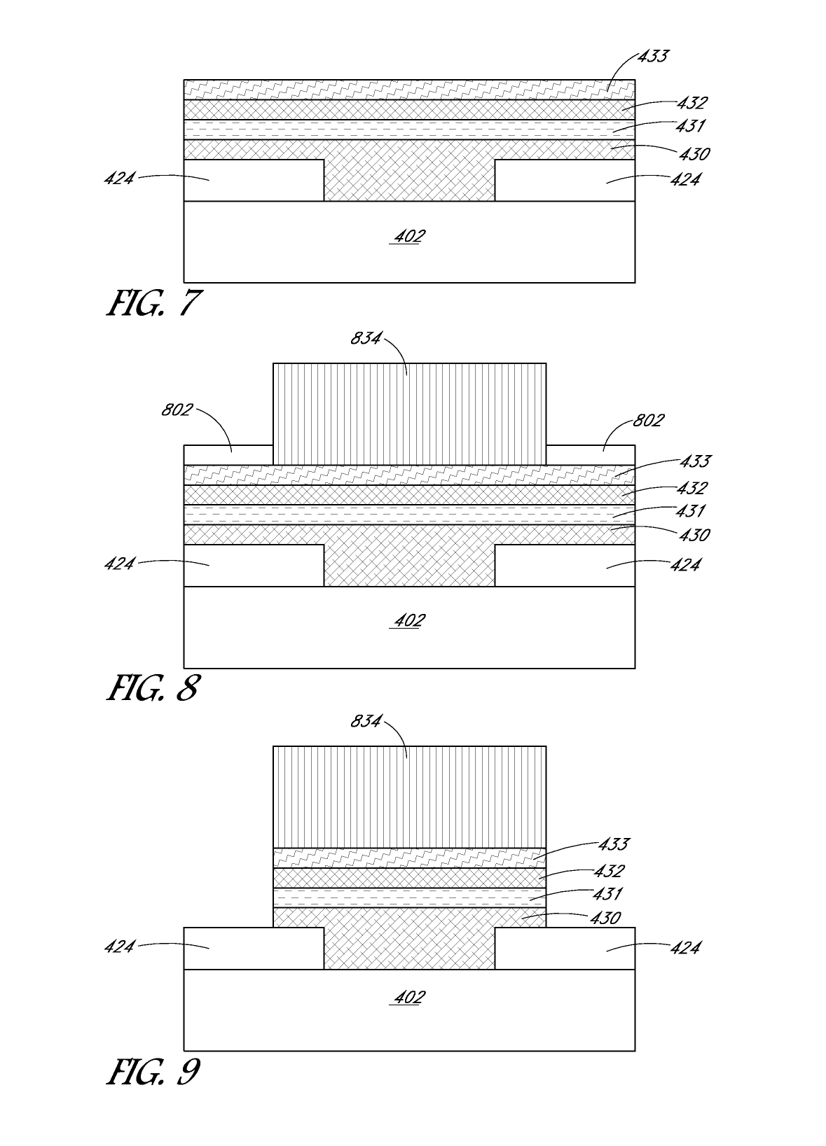

Turning back to FIG. 3 at block 304, and the cross-sectional representation of FIGS. 5 and 6, a multi-layer barrier region can be formed on the first conductive region. Forming the multi-layer barrier region can include forming a first barrier region 431 to inhibit diffusion from or to the first conductive region (e.g., Al) and a second barrier region 432 to inhibit diffusion from or to the second conductive region (e.g., Cu). Similarly, either barrier region can also be configured to inhibit diffusion to or from the other barrier region.

Similar to forming the first conductive region, the multi-layer barrier region can also be formed by deposition. In one embodiment, the layers of the multi-layer barrier region can be applied one layer at a time.

In various examples, and as described throughout the specification, the barrier region closest to the substrate can include Mo and the other barrier region can include one or more of Ti, Ni, V, W among other examples. The collective thickness of the multi-layer barrier region can be approximately 100 nm or less and in some instances, can be approximately 10 nm or less, 20 nm or less, or 60 nm or less, among other examples. By having a thinner barrier region, material cost of the actual metal layers and etchants can be dropped significantly as can processing time (e.g., etch time) by using a single etch process (e.g., a single bath of a dilute solution of ferric chloride, sulfuric acid, phosphoric acid, and peroxide) to etch all the seed stack layers rather than having a separate etchant and separate step for each layer.

Note that in some embodiments, more than two layers can be used in the multi-layer barrier region.

At 306, a second conductive region can be formed over the multi-layer barrier region. An example of the second conductive region being formed is shown in FIG. 7 as second conductive region 433. Second conductive region 433 can be formed as deposited Cu in the range of 50-135 nm. Other metals can also be used instead of Cu.

In some embodiments, the seed stack itself may not have a second conductive region. Instead, in such embodiments, the second conductive region can be plated metal plated directly to the multi-layer barrier region. In one embodiment, plating of the second conductive region to the multi-layer barrier region can be performed after the annealing at block 308.

As shown at 308, the first conductive region, multi-layer barrier region, and second conductive region can be annealed. Annealing can be performed as a forming gas anneal at a temperature below approximately 450 degrees Celsius. Annealing can help improve electrical contact and remove contaminants, and/or sputtering damage.

In one embodiment, the multi-layer barrier region layers can remain substantially separate after annealing such that the layers do not substantially alloy together. Accordingly, layers of the multi-layer barrier region can therefore maintain their respective properties for inhibiting diffusion of certain materials. For example, after annealing, Mo can remain separate from NiV such that the Mo can still inhibit diffusion of Al to Ni and vice versa and NiV can remain separate from the Mo such that the NiV can still inhibit diffusion of Cu to Al or Si and vice versa.

Moreover, in some embodiments, in addition to inhibiting Al from reaching the Ni, the Mo containing layer can also inhibit the Ni from diffusing out of the Ni or Ni alloy layer into the Al. More generally, one of the barrier region layers can be selected such that it can inhibit diffusion out of the other barrier region layer and into either of the conductive layers.

As illustrated at 310, the annealed first conductive region, multi-layer barrier region, and second conductive region can be patterned. Patterning can include etching the first conductive region, multi-layer barrier region, and second conductive region with a single etchant, for example, an etchant that includes a dilute solution of ferric chloride, sulfuric acid, phosphoric acid, and peroxide.

In one embodiment, before patterning the seed stack at 310, a patterned mask, as shown as mask 802 in FIG. 8, can be applied on the seed stack at locations over and between doped regions. Additional conductive material (e.g., Cu, tin), as shown by 834 in FIG. 8, can be plated to the exposed (e.g., not covered with the mask) regions of the seed stack. In an alternate embodiment, additional metal can be formed (e.g., plated) after the seed stack is patterned. A patterned metal contact that can be used as a finger in a solar cell, for example, is shown in FIG. 9.

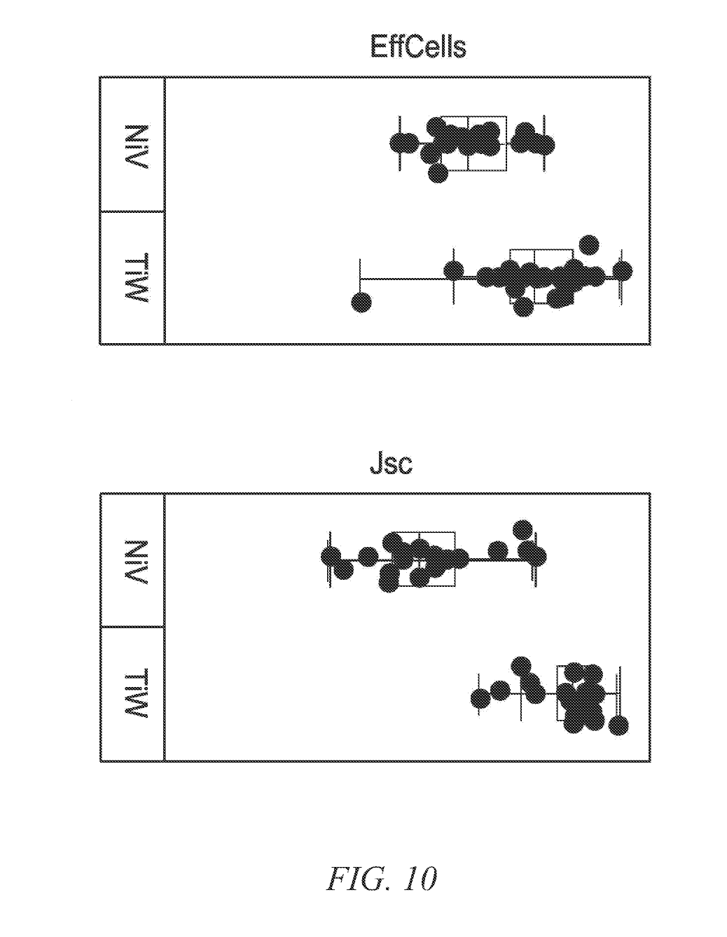

FIGS. 10 and 11 illustrate graphs of efficiency and short circuit current (J_{SC}) for example metallization structures. FIG. 10 specifically shows a comparison of efficiency and J_{SC} in experiments performed on a metal seed stack using NiV as the sole barrier region versus using TiW as the sole barrier region. As shown in the left hand side of FIG. 10, efficiency and J_{SC} are lower for the device using NiV as the sole barrier region. Not shown, similar results exist for a device using Mo as the sole barrier region.

FIGS. 11A and 11B illustrate a comparison of efficiency and J_{SC}, respectively, in experiments performed on a metal seed stack using a multi-layer barrier region with a layer of Mo and a layer of NiV versus using TiW as the sole barrier layer. As shown, the multi-layer barrier region exhibited improved efficiency and J_{SC} over the NiV sole barrier region results in FIG. 10 as well as improved performance over the device that had a TiW barrier region.

FIG. 12 illustrates SEM cross-section images for example metallization structures. Specifically, FIG. 12 illustrates that even with thin layers of the disclosed multi-layer barrier region, such as 5 nm of Mo and 5 nm of NiV in FIGS. 12(a) and 30 nm of Mo and 30 nm of NiV in FIG. 12(b), no significant inter-diffusion of metal layers was observed, which is also reflected in the improved performance shown in FIG. 11. This is in contrast to FIG. 12(c) in which a single layer barrier of NiV was used and where inter-diffusion of Al and Ni was observed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A solar cell, comprising:
a substrate;
a semiconductor region disposed in or above the substrate; and
a conductive contact disposed on the semiconductor region, the conductive contact comprising:
a first conductive region disposed on the semiconductor region,
a first barrier region disposed on the first conductive region,
a second barrier region disposed on the first barrier region, and
a second conductive region disposed over the second barrier region.

2. The solar cell of claim 1, wherein the first barrier region includes a refractory metal.

3. The solar cell of claim 1, wherein the first conductive region includes aluminum and the second conductive region includes copper.

4. The solar cell of claim 1, wherein the first and second barrier regions each have a thickness of approximately 30 nm or less.

5. The solar cell of claim 1, wherein the first barrier region includes molybdenum.

6. The solar cell of claim 1, wherein the second barrier region includes a nickel-vanadium alloy.

7. The solar cell of claim 1, wherein a thickness of the first barrier region is different than a thickness of the second barrier region.

8. The solar cell of claim 1, further comprising a third barrier region disposed on the second barrier region, wherein the second conductive region is disposed on the third barrier region.

9. The solar cell of claim 1, wherein the conductive contact is on a back side of the solar cell opposite a sunny side of the solar cell.

10. The solar cell of claim 1, further comprising additional metal disposed on the second conductive region.

11. A solar cell, comprising:
a monocrystalline silicon substrate;
a semiconductor region disposed in or above the monocrystalline silicon substrate; and
a conductive stack comprising:
a first conductive layer disposed on the semiconductor region;
a plurality of diffusion-barrier conductive layers disposed on the first conductive layer; and
a second conductive layer disposed on the plurality of diffusion-barrier conductive layers.

12. The solar cell of claim 11, wherein the plurality of diffusion-barrier conductive layers comprises a layer of molybdenum and a layer of nickel-vanadium alloy.

13. The solar cell of claim 11, wherein a thickness of a first one of the plurality of diffusion-barrier conductive layers is different than a thickness of a second one of the plurality of diffusion-barrier conductive layers.

14. The solar cell of claim 11, wherein a combined thickness of the plurality of diffusion-barrier conductive layers is less than approximately 20 nm.

15. The solar cell of claim 11, further comprising plated metal disposed on the conductive stack.

16. A method of fabricating a solar cell, the method comprising:
forming a first conductive region on a semiconductor region disposed in or above a substrate;
forming a multi-layer barrier region on the first conductive region;
forming a second conductive region over the multi-layer barrier region.

17. The method of claim 16, further comprising:
annealing the first conductive region, multi-layer barrier region, and second conductive region at a temperature in a range of less than approximately 450° C.; and
patterning the annealed first conductive region, multi-layer barrier region, and second conductive region.

18. The method of claim 17, wherein said patterning includes etching the first conductive region, multi-layer barrier region, and second conductive region with a single etchant.

19. The method of claim 16, further comprising:
annealing the first conductive region, multi-layer barrier region, and second conductive region;
applying a patterned plating resist to the annealed first conductive region, multi-layer barrier region, and second conductive region;
plating a metal onto the first conductive region, multi-layer barrier region, and second conductive region to form a plurality of metal contacts; and
etching portions of the first conductive region, multi-layer barrier region, and second conductive region between the plurality of metal contacts.

20. The method of claim 16, wherein said forming the multi-layer barrier region comprises forming a first barrier layer to inhibit diffusion to or from the first conductive region that includes aluminum and forming a second barrier layer to inhibit diffusion to or from the second conductive region that includes copper.
